(19) United States
(12) Patent Application Publication
(10) Pub. No.: US 2025/0069683 A1
(43) Pub. Date: Feb. 27, 2025

(54) FLEXIBLE ADDRESS SWAP COLUMN REDUNDANCY

(71) Applicant: Micron Technology, Inc., Boise, ID (US)

(72) Inventors: Luyen Vu, San Jose, CA (US); Alex Sheng-Huang Lee, Meridian, ID (US); Wei Lic Chew, Singapore (SG)

(21) Appl. No.: 18/782,624

(22) Filed: Jul. 24, 2024

Related U.S. Application Data
(60) Provisional application No. 63/534,479, filed on Aug. 24, 2023.

(51) Int. Cl. G11C 29/00

(52) U.S. Cl. CPC G11C 29/76; G11C 29/785; G11C 29/808

(57) ABSTRACT

A memory device includes a memory array includes memory cells grouped into one or more address ranges. Control logic is coupled to the memory array and configured to detect one or more errors associated with one or more stored data items corresponding to a first address range of one or more address ranges. The control logic can determine that a number of the one or more stored data items exceeds a number of redundant memory locations for the first address space. Control logic can remap an association of a first memory address of at least one of the stored data items from a first address within the first address space to a second address in a second address range, where the second address range includes one or more available redundant memory locations.

### REFERENCE TO RELATED APPLICATIONS

This application claims the priority benefit of U.S. Provisional Application No. 63/534,479, filed Aug. 24, 2023, which is incorporated by reference herein.

### TECHNICAL FIELD

Embodiments of the disclosure relate generally to memory sub-systems, and more specifically, relate to a flexible address swap column redundancy scheme.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1A illustrates an example computing system that includes a memory sub-system in accordance with some embodiments of the present disclosure.

FIG. 1B is a block diagram of a memory device in communication with a memory sub-system controller of a memory sub-system, in accordance with some embodiments of the present disclosure.

FIG. 2 is a system diagram of an example communication system using a flexible address swap redundancy scheme, in accordance with some embodiments of the present disclosure.

FIG. 3 is a system diagram of an example communication system using a flexible address swap redundancy scheme, in accordance with some embodiments of the present disclosure.

FIG. 4 is a diagram illustrating a flexible address swap column redundancy scheme, in accordance with embodiments of the present disclosure.

FIG. 5 illustrates an example computing system 500 utilizing a flexible address swap column redundancy scheme in accordance with some embodiments of the present disclosure.

FIG. 6 is a flow diagram of an example method for a flexible address swap redundancy scheme, in accordance with some embodiments of the present disclosure.

FIG. 7 illustrates an example machine of a computer system 700 within which a set of instructions, for causing the machine to perform any one or more of the methodologies discussed herein, can be executed.

### DETAILED DESCRIPTION

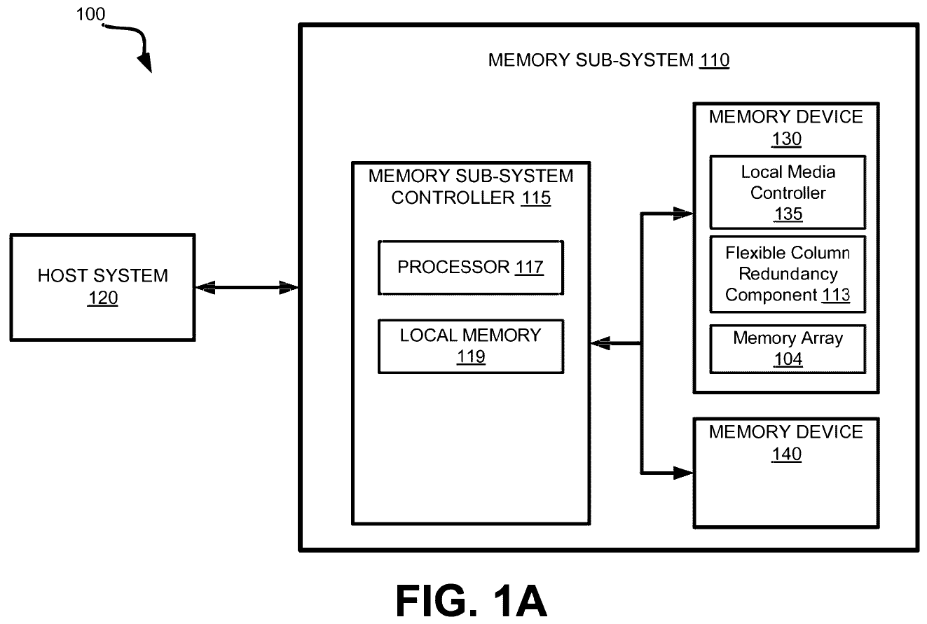

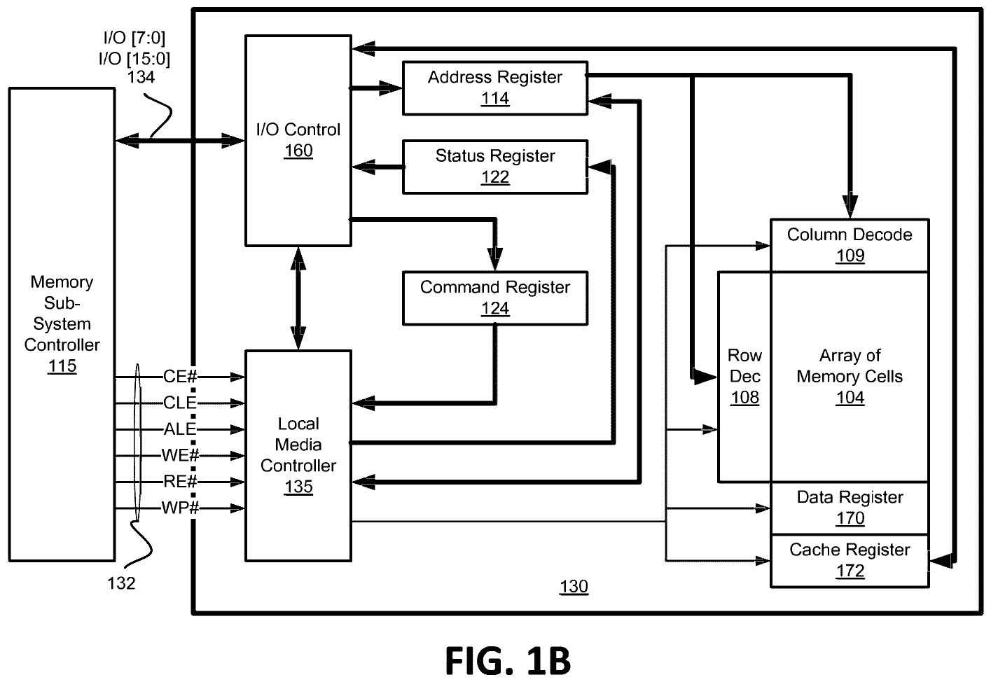

Aspects of the present disclosure are directed to a flexible address swap column redundancy scheme. A memory sub-system can be a storage device, a memory module, or a combination of a storage device and memory module. Examples of storage devices and memory modules are described below in conjunction with FIG. 1A. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. For example, NAND memory, such as 3D flash NAND memory, offers storage in the form of compact, high density configurations. A non-volatile memory device is a package of one or more dice, each including one or more planes. For some types of non-volatile memory devices (e.g., NAND memory), each plane includes a set of physical blocks. Each block includes a set of pages. Each page includes a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1”, or combinations of such values.

A memory device can include multiple memory cells arranged in a two-dimensional or a three-dimensional grid. The memory cells can be formed on a silicon wafer in an array of columns (also hereinafter referred to as bit lines) and rows (also hereinafter referred to as wordlines). A wordline can refer to one or more conductive lines coupled to memory cells of a memory device that are used with one or more bit lines to generate the address of each of the memory cells. The intersection of a bit line and wordline constitutes the address of the memory cell. A block hereinafter refers to a unit of the memory device used to store data and can include a group of memory cells, a wordline group, a wordline, or individual memory cells. One or more blocks can be grouped together to form separate partitions (e.g., planes) of the memory device in order to allow concurrent operations to take place on each plane. Each data block can include a number of sub-blocks, where each sub-block is defined by an associated pillar (e.g., a vertical conductive trace) extending from a shared bit line. Memory pages (also referred to herein as “pages”) store one or more bits of binary data corresponding to data received from the host system. To achieve high density, a string of memory cells in a non-volatile memory device can be constructed to include a number of memory cells at least partially surrounding a pillar of channel material. The memory cells can be coupled to access lines, which are commonly referred to as “wordlines,” often fabricated in common with the memory cells, so as to form an array of strings in a block of memory. The compact nature of certain non-volatile memory devices, such as 3D flash NAND memory, means wordlines are common to many memory cells within a block of memory.

Data (e.g., bytes) stored by a memory device can become defective due to time, temperature, or usage. For example, a memory cell storing a first logic state (e.g., ‘0’) can have a charge level change (e.g., a threshold voltage of the memory cell can be shifted) and during a read operation a second logic state (e.g., ‘1’) can be read instead of the first logic state corresponding to the initial charge level. Defects can be single bit or multi-bit errors and can occur at a string of memory cells, a bit line, or a page buffer. Various solutions can mitigate defects and errors in the memory array by utilizing a column redundancy scheme. For example, the memory array can store data at a certain region. The memory array can also include redundant memory cells which may be utilized to replace defective bits or bytes.

Some solutions may specify the number of redundant bytes for a region of a memory array. For example, the memory array can include rows of memory cells, where each row is associated with the number of redundant bytes. In other solutions, the number of redundant bytes can correspond to a column of memory cells or a page of memory cells, etc. However, some solutions can fail to efficiently mitigate defects and errors in the memory array. For example, one region of the memory array can have more errors than available redundant bytes while another region of the memory array can have little no errors. This can cause the first region to be unable to remedy certain error or defects, even though the overall memory array still includes available redundant bytes. Accordingly, the memory array can be forced to scrap a region of the memory array when the region exhausts available redundant bytes. Trying to increase a number of redundant bytes available for each region requires utilizing additional area and reduces array area efficiency—e.g., more of the array would be dedicated to the redundant bytes hurting the overall utilization of the memory array. Trying to reduce a number of regions in the memory array (e.g., trying to utilize more redundant bytes per region) can force a circuit under array (e.g., a circuit under the memory array) to include additional circuitry and logic, causing an overall increase to the size of a memory die.

Aspects of the present disclosure address the above and other deficiencies by implementing a flexible address swap column redundancy scheme. The memory array can remap an association of a received memory address from within a first address space that has exhausted available redundant memory locations (e.g., extra memory cells that can store copies of data originally stored at a memory cell that is now defective) to a second address space that includes available redundant memory locations. That is, each address space of the memory array can be associated with a row or column of the memory array. During a read operation, an entire address space can be read onto a data bus. A redundant address space (e.g., addresses associated with the extra memory cells that can store copies of data originally stored at memory cells that now defective) can be used to replace one address of a respective address space of the memory array—e.g., when reading the data onto the bus, one redundant address can be read from the redundant address space. Accordingly, if an address space has two or more errors, a memory address associated with one of the errors can be remapped from the first address space to a second address space that has no errors—e.g., to a second address space that has not utilized a redundant address yet. In some examples, any redundant address can be used for replacing the defective memory cell—e.g., the redundant address space as a whole can be associated with the memory array, but any respective redundant address can be used for any of memory array address spaces.

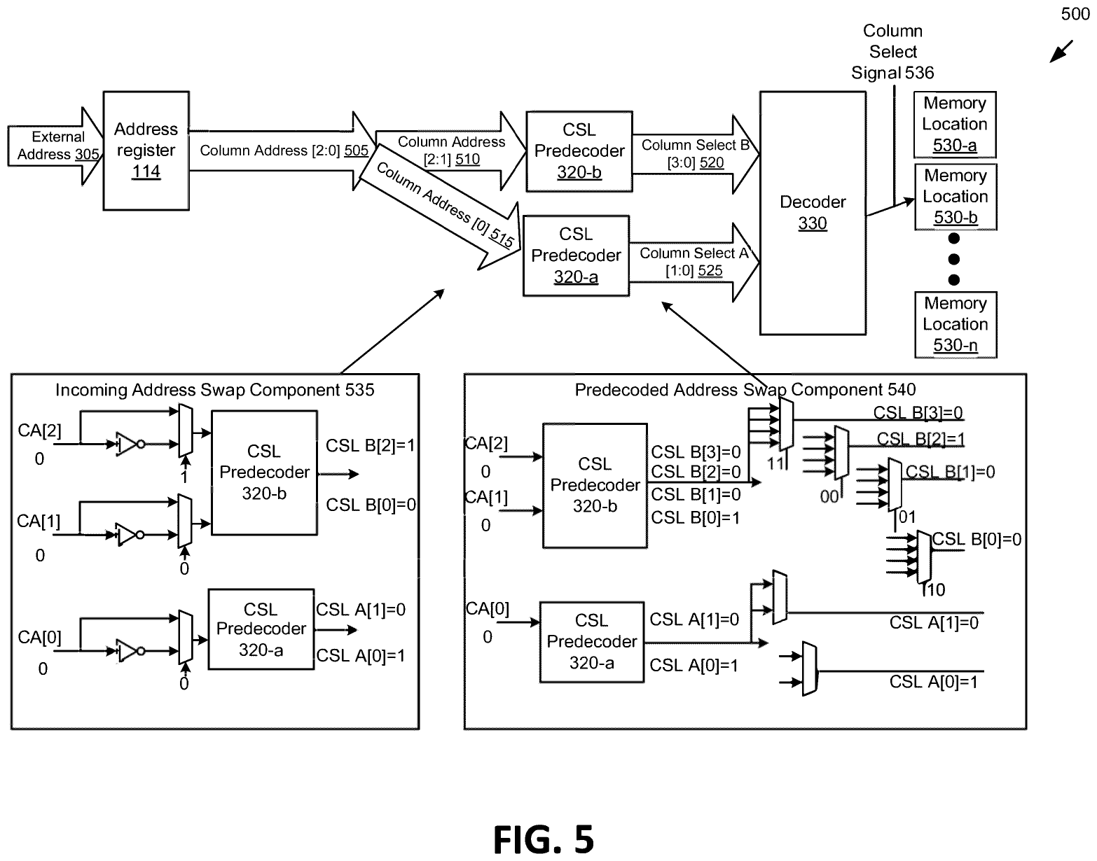

For example, control logic of the memory array can receive a memory address. The control logic can detect one or more errors exhibited by the memory cells identified by the memory address—e.g., determine the memory address contains errors and is associated with a first address range. In such examples, the control logic can attempt to use available redundant memory locations to correct the errors. If the control logic determines there are not enough redundant memory locations to relocate the affected data items (e.g., that the first address range already uses a redundant address to correct an error), the control logic can remap a logical location associated with the memory address from the first address range to a second address range, where the second address range includes available redundant addresses—e.g., the second address range has yet to utilize a redundant address. Accordingly, the control logic can use available redundant memory locations for the second address range to correct the original defect in the first address range. Additional details regarding remapping the memory address from the first address range to the second address range are described with reference to FIG. 5.

By utilizing a flexible address swap column redundancy scheme, the memory array can more efficiently repair defects and errors. For example, the memory array can avoid including additional redundant memory locations or additional circuitry and instead use redundant memory locations across address ranges. Accordingly, the memory device can avoid scrapping memory regions if redundant memory locations associated with the region have been fully utilized.

FIG. 1A illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-system 110. FIG. 1A illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access the memory components (e.g., memory devices 130) when the memory sub-system 110 is coupled with the host system 120 by the PCIe interface. The physical host interface can provide an interface for passing control, address, data, and other signals between the memory sub-system 110 and the host system 120. FIG. 1A illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include negative-and (NAND) type flash memory and write-in-place memory, such as three-dimensional cross-point (“3D cross-point”) memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), and quad-level cells (QLCs), can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, or a QLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor 117 (e.g., a processing device) configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1A has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, a memory device 130 is a managed memory device, which is a raw memory device 130 having control logic (e.g., local controller 135) on the die and a controller (e.g., memory sub-system controller 115) for media management within the same memory device package. An example of a managed memory device is a managed NAND (MNAND) device. Memory device 130, for example, can represent a single die having some control logic (e.g., local media controller 135) embodied thereon. In some embodiments, one or more components of memory sub-system 110 can be omitted.

In one embodiment, memory device 130 includes a flexible column redundancy component 113. In some embodiments, flexible column redundancy component 113 can repair errors that occur at memory array 104. For example, the flexible column redundancy component 113 can fix errors at the memory array 104 by replacing bytes stored at memory array 104 with redundant bytes—e.g., the flexible column redundancy component 113 can remap an association of a memory address from a first address range associated with a defective memory cell to a second address range associated with available redundant memory locations—e.g., to a second address range that has not utilized a redundant address. Accordingly, the data associated with the memory address is stored at the redundant memory locations rather than at the defective memory cell in the first address range. In some embodiments, the memory cells of the memory array can be addressable by respective addresses which can be grouped into one or more address ranges. A redundant address range for the memory array can be associated with the collective address ranges—e.g., any respective redundant address of the redundant address range can be used to fix one or more errors at a respective address range of the memory array. In one embodiment, the flexible column redundancy component 113 can receive a memory address associated with an address range (e.g., associated with a first address range of a plurality of address ranges associated with the memory array 104). In some embodiments, the flexible column redundancy component 113 can determine one or more physical locations associated with the memory address by looking up a received memory address in an address table—e.g., determine a physical location associated with a received logical address, where the table stores the physical location for each logical address. In some embodiments, the flexible column redundancy component 113 can detect (e.g., by receiving an indication from an error correction code (ECC) component) one or more errors associated with the received memory address. In such embodiments, the flexible column redundancy component 113 can also determine whether there are any available redundant bytes for the address range. That is, each address range can be read in its entirety onto a bus during a read operation. In some examples, an address of the address range can be replaced by an address of the redundant address range—e.g., the bus can read one redundant address when reading a respective memory address range. Accordingly, if there are more than one errors in an address range, the flexible column redundancy component 113 can remap a memory address associated with an error from a first address range to a second address range that has not utilized a redundant address yet.

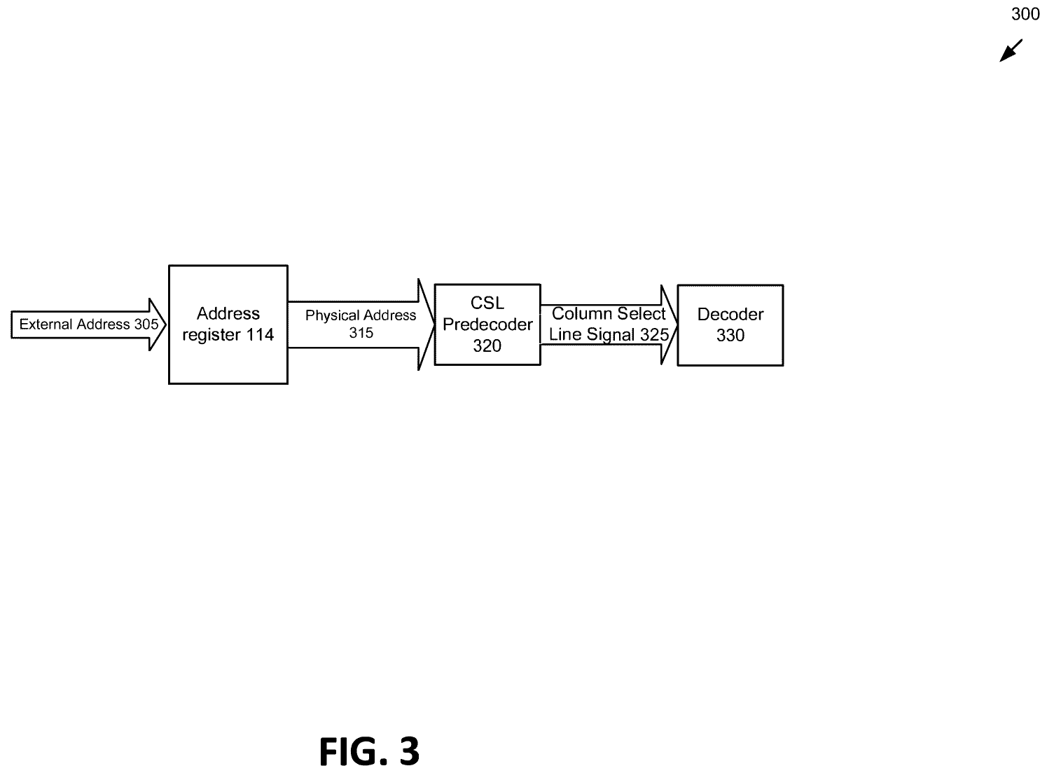

In some embodiments, the flexible column redundancy component 113 can determine there are available redundant memory addresses for the address range and proceed with fixing the one or more errors—e.g., proceed with remapping the memory address from a first address range associated with the defective memory cells to a second address range with an available redundant memory location or address. In other embodiments, the flexible column redundancy component 113 can determine there are not enough available redundant memory locations for the address range—e.g., a number of errors within the address range exceed a number of available redundant memory locations for the address range. In such embodiments, the flexible column redundancy component 113 can transmit an indication to a predecoder (e.g., predecoder 320 as described with reference to FIG. 3) to remap the memory address from a first address a second address associated with as second address range. In some embodiments, the second address range can include available redundant memory locations. In some embodiments, a decoder can receive the updated or remapped address and determine the second address in the second address space corresponds to the received memory address. Accordingly, flexible column redundancy component 113 can repair the errors by utilizing the redundant bytes of the second address range.

In some embodiments, the memory sub-system controller 115 includes at least a portion of flexible column redundancy component 113. For example, the memory sub-system controller 115 can include a processor 117 (e.g., a processing device) configured to execute instructions stored in local memory 119 for performing the operations described herein. In some embodiments, flexible column redundancy component 113 is part of the host system 120, an application, or an operating system. In other embodiment, local media controller 135 includes at least a portion of flexible column redundancy component 113 and is configured to perform the functionality described herein. In such an embodiment, flexible column redundancy component 113 can be implemented using hardware or as firmware, stored on memory device 130, executed by the control logic (e.g., flexible column redundancy component 113) to perform the operations related to program recovery described herein.

FIG. 1B is a simplified block diagram of a first apparatus, in the form of a memory device 130, in communication with a second apparatus, in the form of a memory sub-system controller 115 of a memory sub-system (e.g., memory sub-system 110 of FIG. 1A), according to an embodiment. Some examples of electronic systems include personal computers, personal digital assistants (PDAs), digital cameras, digital media players, digital recorders, games, appliances, vehicles, wireless devices, mobile telephones and the like. The memory sub-system controller 115 (e.g., a controller external to the memory device 130), may be a memory controller or other external host device. The memory sub-system controller 115 can include the flexible column redundancy component 113.

Memory device 130 includes an array of memory cells 104 logically arranged in rows and columns. Memory cells of a logical row are typically connected to the same access line (e.g., a wordline) while memory cells of a logical column are typically selectively connected to the same data line (e.g., a bit line). A single access line may be associated with more than one logical row of memory cells and a single data line may be associated with more than one logical column. Memory cells (not shown in FIG. 1B) of at least a portion of array of memory cells 104 are capable of being programmed to one of at least two target data states. In one embodiment, the array of memory cells 104 (i.e., a “memory array”) can include a number of sacrificial memory cells used to detect the occurrence of read disturb in memory device 130, as described in detail herein.

Row decode circuitry 108 and column decode circuitry 109 are provided to decode address signals. Address signals are received and decoded to access the array of memory cells 104. Memory device 130 also includes input/output (I/O) control circuitry 160 to manage input of commands, addresses and data to the memory device 130 as well as output of data and status information from the memory device 130. An address register 114 is in communication with I/O control circuitry 160 and row decode circuitry 108 and column decode circuitry 109 to latch the address signals prior to decoding. A command register 124 is in communication with I/O control circuitry 160 and local media controller 135 to latch incoming commands.

A controller (e.g., the local media controller 135 internal to the memory device 130) controls access to the array of memory cells 104 in response to the commands and generates status information for the external memory sub-system controller 115, i.e., the local media controller 135 is configured to perform access operations (e.g., read operations, programming operations and/or erase operations) on the array of memory cells 104. The local media controller 135 is in communication with row decode circuitry 108 and column decode circuitry 109 to control the row decode circuitry 108 and column decode circuitry 109 in response to the addresses. In one embodiment, local media controller 135 can include (e.g., include at least a portion of) a flexible column redundancy component 113 as described with reference to FIG. 1B.

The local media controller 135 is also in communication with a cache register 172. Cache register 172 latches data, either incoming or outgoing, as directed by the local media controller 135 to temporarily store data while the array of memory cells 104 is busy writing or reading, respectively, other data. During a memory access operation (e.g., write operation), data may be passed from the cache register 172 to the data register 170 for transfer to the array of memory cells 104; then new data may be latched in the cache register 172 from the I/O control circuitry 160. During a read operation, data may be passed from the cache register 172 to the I/O control circuitry 160 for output to the memory sub-system controller 115; then new data may be passed from the data register 170 to the cache register 172. The cache register 172 and/or the data register 170 may form (e.g., may form a portion of) a page buffer of the memory device 130. A page buffer may further include sensing devices (not shown in FIG. 1B) to sense a data state of a memory cell of the array of memory cells 104, e.g., by sensing a state of a data line connected to that memory cell. A status register 122 may be in communication with I/O control circuitry 160 and the local memory controller 135 to latch the status information for output to the memory sub-system controller 115.

Memory device 130 receives control signals at the memory sub-system controller 115 from the local media controller 135 over a control link 132. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) may be further received over control link 132 depending upon the nature of the memory device 130. In one embodiment, memory device 130 receives command signals (which represent commands), address signals (which represent addresses), and data signals (which represent data) from the memory sub-system controller 115 over a multiplexed input/output (I/O) bus 236 and outputs data to the memory sub-system controller 115 over I/O bus 134.

For example, the commands may be received over input/output (I/O) pins [7:0] of I/O bus 134 at I/O control circuitry 160 and may then be written into command register 124. The addresses may be received over input/output (I/O) pins [7:0] of I/O bus 134 at I/O control circuitry 160 and may then be written into address register 114. The data may be received over input/output (I/O) pins [7:0] for an 8-bit device or input/output (I/O) pins [15:0] for a 16-bit device at I/O control circuitry 160 and then may be written into cache register 172. The data may be subsequently written into data register 170 for programming the array of memory cells 104.

In an embodiment, cache register 172 may be omitted, and the data may be written directly into data register 170. Data may also be output over input/output (I/O) pins [7:0] for an 8-bit device or input/output (I/O) pins [15:0] for a 16-bit device. Although reference may be made to I/O pins, they may include any conductive node providing for electrical connection to the memory device 130 by an external device (e.g., the memory sub-system controller 115), such as conductive pads or conductive bumps as are commonly used.

It will be appreciated by those skilled in the art that additional circuitry and signals can be provided, and that the memory device 130 of FIG. 1B has been simplified. It should be recognized that the functionality of the various block components described with reference to FIG. 1B may not necessarily be segregated to distinct components or component portions of an integrated circuit device. For example, a single component or component portion of an integrated circuit device could be adapted to perform the functionality of more than one block component of FIG. 1B. Alternatively, one or more components or component portions of an integrated circuit device could be combined to perform the functionality of a single block component of FIG. 1B. Additionally, while specific I/O pins are described in accordance with popular conventions for receipt and output of the various signals, it is noted that other combinations or numbers of I/O pins (or other I/O node structures) may be used in the various embodiments.

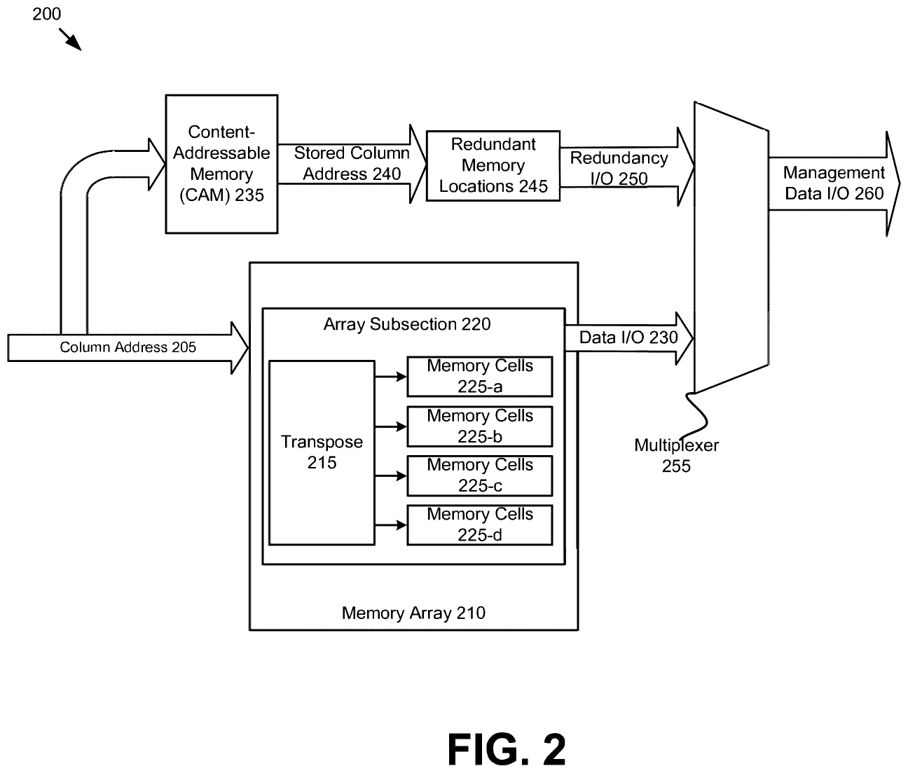

FIG. 2 illustrates an example computing system 200 utilizing a flexible address swap column redundancy scheme in accordance with some embodiments of the present disclosure. For example, system 200 can repair one or more errors that occur at memory array 104 as described with reference to FIG. 1. In some embodiments, system 200 can be located in flexible column redundancy component 113 or local media controller 135 as described with reference to FIG. 1A. In some embodiments, a portion of system 200 can be included in the flexible column redundancy component 113 or local media controller 135. System 200 can receive a memory address and output at least a physical address associated with the received memory address—e.g., the received memory address can be a logical address and the system 200 can be configured to output a physical address associated with the received logical address. In some embodiments, system 200 is configured to output the physical address to a data bus—e.g., system 200 can be coupled to a data bus. System 200 can include memory array 210 which includes memory array subsection 220 and a transpose component 215. System 200 can also include a content address memory (CAM) 235, redundant memory locations 245 (e.g., spare memory cells that can store copies of data originally stored at memory cells of the memory array 210 that are now defective), and a multiplexer 255. In some embodiments, system 200 can include an additional CAM to control the transpose component 215. In some embodiments, CAM 235 can control transpose component 215.

In one embodiment, memory array 210 can store data associated with a host system (e.g., host system 120 as described with reference to FIG. 1A). In some embodiments, the memory array 210 can include a plurality of memory cells (e.g., memory cells 225-a, memory cells 225-b, memory cells 225-c, memory cells 225-d, etc.) to store data. In some embodiments, memory array 210 can be divided into array subsections 220. That is, although one (1) array subsection 220 is illustrated in FIG. 2, the memory array 210 can have any number of array subsections 220. In some embodiments, each array subsection 220 can include groups of memory cells 225 each associated with a different address range. For example, memory cells 225-a can be associated with a first address range, memory cells 225-b can be associated with a second address range, memory cells 225-c can be associated with a third address range, and memory cells 225-d can be associated with a fourth address range. In some embodiments, the address range can refer to a collection of row addresses or column addresses—e.g., the address range can refer to a physical row of memory cells or a physical column of memory cells. In other examples, the address range can refer to a different division of memory cells—e.g., to a page of memory cells.

In some embodiments, the memory array 210 can receive a column address 205—e.g., receive a column address 205 from a local media controller 135 or a memory sub-system controller 115 as described with reference to FIG. 1. In some embodiments, each array subsection 220 can include a transpose component 215. In some embodiments, the transpose component 215 can transpose or remap a first address of a first address range associated with the received column address 205 to a second address in a second address range. For example, the column address 205 can indicate a first physical location corresponding to one or more memory cells 225-a. The transpose component 215 can be configured to remap the first physical location from being associated with a first address range to being associated with a second address range. In one embodiment, the transpose component 215 is configured to remap the physical addresses when there are no available redundant memory locations 245 are available for an address range—e.g., no available redundant memory locations 245 for the address range corresponding to memory cells 225-a. In some embodiment, memory array 210 can output a data input/output (I/O) 230. In some embodiments, the data I/O 230 can indicate a physical location associated with column address 205. In some embodiments, data I/O 230 can include data associated with the column address 205. In at least one embodiment, transpose component 215 can swap an address at a predecoder as described with reference to FIG. 5—e.g., the transpose component 215 can include a predecoder with one or more multiplexers that the transpose component 215 can send signals to in order to swap an address. In other embodiments, the transpose component 215 can remap the address by performing inverting the address before it is received at the predecoder as described with reference to FIG. 5.

In some embodiments, content-addressable memory (CAM) 235 can store a respective physical address (e.g., physical location) associated with all logical addresses received from a host system or memory sub-system controller—e.g., the CAM 235 can compare a memory address received with table of stored memory addresses, where the table indicates a physical location associated with the stored memory address. For example, the CAM 235 can receive the column address 205. In some embodiments, the CAM 235 can compare the received column address 205 with stored column addresses to determine a physical location associated with the column address 205—e.g., the CAM 235 can be configured to map between the logical address received and a physical address where the data is stored. In some embodiments, the CAM 235 can also store an indication of any redundant memory locations 245 utilized for the respective column address 205 received. In at least one embodiment, the system 200 can determine a number of available redundant memory locations for a respective address range based on a comparison between the column address 205 and the stored column address 240. For example, system 200 can determine a number of redundant memory locations utilized based on the physical locations output by the CAM 235. In such embodiments, the system 200 can determine the number of available redundant memory locations by subtracting the utilized redundant memory locations 245 from a threshold number of redundant memory locations 245 for with the address range. In one embodiment, the CAM 235 is configured to output the stored column address 240—e.g., output a real address indicating a physical location of data associated with the column address 205.

In some embodiments, redundant memory locations 245 can replace or repair errors associated with data stored at the memory array 210—e.g., the system 200 can remap a physical location associated with a received memory address from a first physical location corresponding to a defective memory cell at memory array 210 to a second physical location corresponding to a redundant memory location stored at redundant memory locations 245. In some embodiments, there can be a threshold number of redundant memory locations available to use for each address space—e.g., there can be a set number of redundant memory locations each address space can use. For example, during a read operation an entire respective address range can be read onto a data bus. In such examples, a threshold number of addresses of the respective address range can be replaced by a redundant memory location(s) 245. When the threshold number of addresses that can be replaced is satisfied, additional addresses of the respective address range cannot be replaced. Accordingly, the received address can be mapped from the respective address range to a second address range that has not satisfied the threshold number of addresses that can be replaced. In at least one embodiment, the threshold number of addresses that can be replaced can be based on a size of the array, an ECC limit, or a memory management algorithm (e.g., an algorithm programmed to the system 200 that indicates types of errors to correct using redundant memory locations). In some embodiments, the redundant memory locations 245 can receive stored column address 240 and output redundancy input/output (I/O) 250—e.g., the redundant memory locations 245 component can receive the stored column address 240, determine the physical location of the redundant memory locations storing the associated data, and output the redundant memory locations 245.

In some embodiments, multiplexer 255 can receive data I/O 230 from memory array 210 and redundancy I/O 250 from redundant memory locations 245. In one embodiment, the system 200 can determine a number of redundant memory locations available for a respective address range based on a number of redundant memory locations 245 in the redundancy I/O 250—e.g. the system 200 can subtract a number of redundant memory locations 245 output from the threshold number of redundant memory locations or threshold number of number of addresses that can be replaced. In some embodiments, the system 200 can determine that one or more errors associated with the column address 205 exceeds a number of redundant memory locations 245 available for the respective address range. In such embodiments, the system 200 can remap a first address associated with the received memory address and corresponding to the first address range to a second address associated with a second address range at the transpose 215, where the second address range includes available redundant memory locations.

Accordingly, the system 200 can repair errors even if a respective address range has no available redundant memory locations. In at least one embodiment, the multiplexer 255 is configured to output a management data input/output (I/O) 260. In some embodiments, the management data I/O 260 can represent a serial bus used to manage physical components or physical layers of memory device 130 described with reference to FIG. 1A. The management data I/O 260 can include an operation code, a physical address, a register address, and/or data.

FIG. 3 illustrates an example computing system 300 utilizing a flexible address swap column redundancy scheme in accordance with some embodiments of the present disclosure. For example, system 300 can be configured to repair one or more errors that occur at memory array 104 as described with reference to FIG. 1. In some embodiments, system 300 can be located in flexible column redundancy component 113 or local media controller 135 as described with reference to FIG. 1A. In some embodiments, portions of system 300 can be included in system 200 as described with reference to FIG. 2. In some embodiments, system 300 can be configured to receive an external address 305 and determine a physical location of bytes associated with the received external address 305. In some embodiments, system 300 can include an address register 114, a column select predecoder 320, and a decoder 330.

In some embodiments, address register 114 can store physical addresses (e.g., physical locations) and determine a physical address where the data resides for received memory addresses. For example, the address register 114 can receive an external address 305 (e.g., a logical address associated with a host system) and use a stored table to look up an internal address 315 (e.g., a physical address associated with a location storing the data) corresponding to the external address 305. In some embodiments, the address register 114 is represented by the address register 114 of FIG. 1B. In some embodiments, the address register 114 is included in CAM 235 as described with reference to FIG. 2. In at least one embodiment, the system 300 can update the tables stored at address register 114 when an internal address 315 is changed—e.g., the system 300 can update the tables stored at the address register 114 when a first address associated with a first address range is remapped to a second address associated with a second address range to use available redundant memory locations at the second address range as described with reference to FIG. 2.

In one embodiment, column select line (CSL) predecoder 320 can receive the internal address 315 from the address register 114. In some embodiments, the CSL predecoder 320 is configured to generate a column select line (CSL) signal 325 for the decoder 330. For example, the CSL predecoder 320 can generate a signal indicating a column associated with the internal address 315. That is, the CSL predecoder 320 can generate a selection control signal dictating which column the decoder 330 should select. In at least one embodiment, the system 300 can swap a first address associated with a first address range to a second address associated with a second address range as described with reference to FIG. 2—e.g., the system 300 can swap the first address when the first address range includes one or more errors to be repaired but no additional redundant addresses can be utilized for the first address range. In some embodiments, the system 300 can remap the incoming address associated with a first location to a second physical location the addresses before or after the CSL predecoder 320 receives the incoming address as described with reference to FIG. 5. For example, the system 300 can perform an incoming address remap and change the address prior to the CSL predecoder 320 receiving the address. In some embodiments, the system 300 can perform a predecoded address swap and change the address after the CSL predecoder 320 outputs the CSL signal 325 as described with reference to FIG. 5. In either embodiment, the decoder 330 can be configured to receive the remapped address in embodiments where system 300 swaps the first address to the second address.

In an embodiment, the decoder 330 can receive the column select line signal 325 and select one or more memory cells associated with the received column select line signal 325. For example, the decoder 330 can receive the CSL signal 325 and select a first memory cell in a column associated with the column select line signal 325. As described with reference to the CSL predecoder 320, in some embodiments the decoder 330 can receive an altered address than the one generated by the address register 114—e.g., the system 300 can swap the address due to an address range including one or more errors and a lack of available of redundancy memory locations. In such embodiments, the decoder 330 can select the updated or new memory cell—e.g., the decoder 330 can select the memory locations associated with the second physical address.

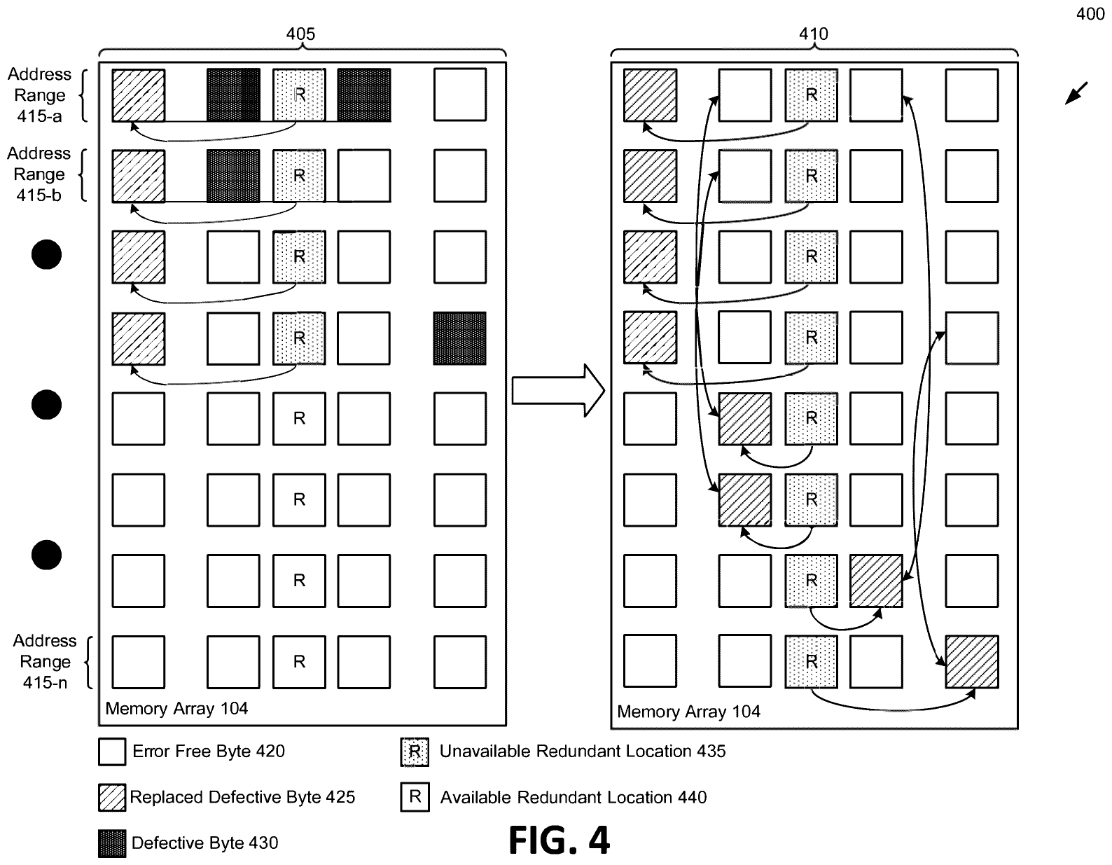

FIG. 4 illustrates an example diagram 400 utilizing a flexible address swap column redundancy scheme in accordance with some embodiments of the present disclosure. In one embodiment, diagram 400 illustrates a memory array 104 (e.g., memory array 104 as described with reference to FIG. 1A) at a first time 405 and a second time 410. In one embodiment, memory array 104 can include memory cells addressable by respective address of an n number of address ranges 415, where each address range includes four (4) bytes (e.g., four memory cells) and one redundant location. It should be note diagram 400 illustrates one possible example of a memory array 104, other examples are possible—e.g., each address range 415 can include any number of bytes or memory cells, any number of redundant locations, and any number of errors other than those illustrated in diagram 400.

At a time 405, memory array 104 can detect (e.g., an ECC component within memory device 130 as described with reference to FIG. 1) one or more errors in the array. For example, the memory array 104 can determine three (3) defective bytes 430 associated with address range 415-a, two (2) defective bytes 430 associated with address range 415-b, one (1) defective byte 430 associated with address range 415-c, and two (2) defective bytes 430 associated with address range 415-d. In at least one embodiment, the memory array 104 can utilize an algorithm (e.g., a memory management algorithm) to determine whether or not repair the determined errors. For example, the memory management algorithm can indicate a type of errors to correct based on a capability of the memory device 130 or based on a testing or manufacturing process—e.g., a testing operation can indicate what types of errors the memory device 130 can refrain from fixing while staying below ECC limits. In one embodiment, the memory array 104 can determine to fix all the defective bytes 430.

As described with reference to FIG. 1A, each address range 415 can use a threshold number of redundant locations or redundant address. Diagram 400 illustrates one available redundant location 440 for each address range 415—e.g., each address range 415 can use one redundant location 440. It should be noted that each address range 415 can use any of the available redundant locations 440—e.g., although a redundant location 440 is shown in each address range 415, the redundant location 440 can be used for an address range 415. For example, the redundant location 440 shown for address range 415-n can be used to replace an error for any of the other address ranges 415. In that, a redundant address of the redundant address range can be used to replace an address of any address range 415. In this example, the memory array can utilize the redundant locations in address ranges 415-a through 415-d for the repair—e.g., address range 415-a through 415-d can have an unavailable redundant location 435 after repairing at least one error in each respective address range 415. For example, the memory array 104 can remap an association of the received memory address from a first physical location associated with the defective byte 430 to a second physical location associated with the unavailable redundant location 435. After utilizing the redundant location for each of the address ranges 415-a through 415-d, the memory array 104 can still include defective bytes 430—e.g., the memory array 104 can determine a number of errors associated with a respective address range 415 fails to satisfy (e.g., exceeds) a number of available redundant bytes for the address range 415. For example, after the repair the address range 415-a can include one (1) replaced defective byte 425 and two (2) defective bytes 430, address range 415-b can include one (1) replaced defective byte 425 and one defective byte 430, address range 415-c can include one (1) replaced defective byte 425, and address range 415-d can include one (1) replaced defective byte 425 and one (1) defective byte 430. In one embodiment, the memory array 104 can utilize the flexible address swap column redundancy scheme as described herein to replace the remaining defective bytes between a time 405 and time 410.

In one embodiment, after time 405 the memory array 104 can detect one or more available redundant bytes 440 (e.g., those shown in address ranges 415-e through 415-n, although the redundant bytes 440 can be available for any address range 415 and are not associated with a respective address range 415 but rather associated with the address range 415-a through address range 415-n as a whole). In such embodiments, the memory array 104 can remap defective byes 430 to a respective address ranges 415-e through 415-n to utilize the available redundant locations 440. For example, remap an association with a memory address from a defective byte 430 from address range 415-a with an error free byte 420 from address range 415-e—e.g., remap from a first address (e.g. left most defective byte 430 illustrated at time 405) to a second address (e.g., the error free byte 420 of address range 415-e). In at least one embodiment, the memory array 104 can utilize the available redundant location 440 for address range 415-e to repair the defective byte 430 remapped from address range 415-a—e.g., at the time 410, the address range 415-e can include a replaced defective byte 425 and an unavailable redundant location 435 after repairing the remapped defective byte 430 from address range 415-a. For example, the memory array 104 can remap from the first address to the available redundant location 440 for address range 415-e. The memory array 104 can proceed with replacing the remaining defective bytes 430 illustrated at time 405 in a similar fashion.

For example, the memory array can remap from a defective byte 430 from address range 415-b to an error free byte 420 from address range 415-f, and then utilize the available redundant location 440 to repair the defective byte 430—e.g., at the time 410 the address range 415-f can include a replaced defective byte 425 and an unavailable redundant location 435 after the defective byte 430 is swapped from address range 415-b to address range 415-f. In one embodiment, the memory array can also remap a memory address association from a second defective byte 430 (e.g., right most defective byte 430 illustrated at a time 405) of address range 415-a to an error free byte 420 of address range 415-g, and then utilize the available redundant location 440 for address range 415-g to repair the defective byte 430—e.g., at the time 410 the address range 415-g can include a replaced defective byte 425 and an unavailable redundant location 435 after the defective byte 430 is remapped from address range 415-a to address range 415-g. In some embodiments, the memory array can further remap a defective byte 430 of address range 415-d with an error free byte 420 of address range 415-n, and then utilize the available redundant location 440 for address range 415-n to repair the defective byte 430—e.g., at the time 410 the address range 415-n can include a replaced defective byte 425 and an unavailable redundant location 435 after the defective byte 430 is remapped from address range 415-d to address range 415-n. Accordingly, the memory array 104 can repair all defective bytes 430 even though at the time 405 a number of errors in address range 415-a, address range 415-b, and address range 415-d failed to satisfy (e.g., exceeded) a number of available redundant locations for the respective address range.

FIG. 5 illustrates an example computing system 500 utilizing a flexible address swap column redundancy scheme in accordance with some embodiments of the present disclosure. For example, system 500 can be configured to repair one or more errors that occur at memory array 104 as described with reference to FIG. 1. In some embodiments, system 500 can be located in flexible column redundancy component 113 or local media controller 135 as described with reference to FIG. 1A. In some embodiments, portions of system 500 can be included in system 200 or system 300 as described with reference to FIGS. 2 and 3. In some embodiments, system 500 can be configured to receive an external address 305 and determine an internal memory location 530 to access as described herein. In some embodiments, system 500 can include an address register 114, a column select predecoder 320, and a decoder 330. The system 500 can also include one or more memory locations 530 (e.g., physical memory cells storing data) and include either an incoming address swap component 535, a predecoded address swap component 540, or both.

In at least one embodiment, the system 500 can receive an external address 305 as described with reference to FIG. 3. In at least one embodiment, the address register 114 can receive the external address 305 and determine a corresponding column address 505—e.g., a column address 505 associated with the incoming external address 305. In at least one embodiment, the address register 114 can include or be an example of content-addressable memory (CAM) 235 as described with reference to FIG. 2. In at least one embodiment, the address register 114 can transmit the column address to one or more column select line (CSL) predecoders 320.

In at least one embodiment, CSL predecoders 320 can be part of the transpose 215 as described with reference to FIG. 2. In one embodiment, each predecoder 320 can predecode a subset of an address space—e.g., a subset of the column address 505 received from the address register 114. For example, the column address 505 can be [2:0] and be broken into a first column address 510 that includes [2:1] and a second column address 515 that includes [0]. Accordingly, each CSL predecoder 320 can receive a respective column address 505 or 510 and output a column select signal (e.g., column select B 520 or column select A 525) to a decoder 330. In one embodiment, the decoder 330 can be an example of AND logic and can select, by the column select signal 536, a memory location 530 based on the received column select signals.

In one embodiment, a column address can be swapped or otherwise modified before it is received by the decoder 330. For example, as described with reference to FIGS. 2-4, redundant memory locations can replace or repair errors associated with data stored at the memory array. When there are no additional redundant memory locations available to use for a respective address space, the system 500 can remap an association of the external address 305 from a first address space to a second address space. In at least one embodiment the system 500 can remap the association at the incoming address swap component 535. In another embodiment, the system 500 can remap the association at the predecoded address swap component 540. In some embodiments, the system 500 can include both the incoming address swap component 535 and the predecoded address swap component 540.

For example, the incoming address swap component 535 can receive a column address associated with each address space—e.g., receive column address (CA) [2], CA [1], and CA [0]. In at least one embodiment, the external address 305 can originally be associated with CSL A[0] and CSL B[0]. In such embodiments, ordinarily the CSL predecoder 320-a can output a value CSL A[0]=1 (e.g., a signal indicating the external address 305 is associated with A[0]) and a value CSL B[0]=1 (e.g., a signal indicating the external address 305 is also associated with B[0]). In embodiments where the system 500 performs a remapping though, the CAM can transmit a signal to one or more respective circuits coupled to the CSL predecoders 320 in order to swap the column address. For example, FIG. 5 illustrates the CA [2] circuit can receive a signal (e.g., receive a one (1) from the CAM) and cause a change in the output of the CSL predecoder 320. That is, the CAM can store locations of errors and also store whether an address is associated with a redundant memory location. In at least one embodiment, the CAM can determine where to remap the incoming memory address to and accordingly transmit signals as needed to the circuits before the predecoders receive the address. As illustrated in FIG. 5, by transmitting the one (1) to the CA [2] circuit, the CSL predecoder can output a value CSL B[2]=1 and CSL B[0]=0—e.g., output a column select signal that indicates to select B[2] rather than B[0]. Accordingly, the decoder 330 can select a memory location 530-b instead of a memory location 530-a based on the incoming address swap component 535 swapping CSL B[0] to zero (0) and swapping CSL B[2] to one (1). In that, CSL predecoder 320-b can output a different column select B [3:0] 520 when the incoming address swap component 535 swaps an address before it is received at a respective predecoder 320.

In other embodiments, the system 500 can swap the address after the CSL predecoders 320 output a column select signal (e.g., a column select B 520 or column select A 525). For example, the external address can again be associated with A[0] and B[0] originally. Accordingly, the CSL pre-decoder 320-b can output a one (1) for the address space B[0](e.g., B[0] can go high) and output a zero (0) for the remaining address spaces (e.g., B[1], B[2], and B[3] can go low). Similarly, CSL predecoder 320-a can output a CSL A[0]=1 and CSL A[1]=0 to select the A[0] address space. In embodiments where an address is swapped, a CAM can transmit a signal to one or more multiplexers coupled to the CSL predecoders 320. For example, each multiplexer can receive all CSL select values output by a respective predecoder 320—e.g., each multiplexer coupled to CSL predecoder 320-b can receive CSL B[0] through B[3]. The multiplexers can also receive a signal from the CAM (e.g., a signal ‘11’, ‘00’, ‘01’, or ‘10’). In some embodiments, the received signal can cause a column select signal to be swapped from one address space to another. For example, by transmitting a ‘10’ to the multiplexer associated with B[0] and a ‘00’ to a multiplexer associated with B[2], the column select signal for B[0] can go to zero (0) and the column select signal for B[2] can go to one (1). Accordingly, CSL B[2] goes high and is selected instead of CSL B[0]. In such embodiments, the decoder 330 can select memory location 530-b rather than memory location 530-a as a result of the address swap at the predecoded address swap component 540.

It should be noted that a number of address spaces associated with a column address is shown for illustrative purposes only. The column address can have any number of address spaces. Additionally, the column address can be broken into any number of subsets for any number of predecoders—e.g., the system 500 can include additional CSL predecoders based on a number of subsets of the column address 505. By remapping the address at either the incoming address swap component 535 or the predecoded address swap component 540, the system 500 can utilize a flexible address swap column redundancy scheme to repair or fix errors at address spaces that cannot use additional redundant memory locations.

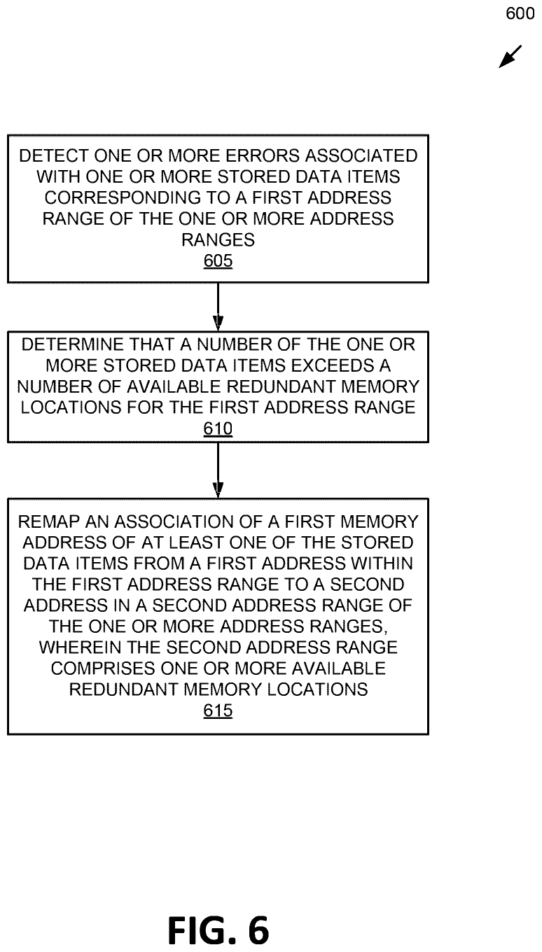

FIG. 6 is a flow diagram of an example method for a flexible address swap redundancy scheme, in accordance with some embodiments of the present disclosure. The method 600 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 600 is performed by local media controller 135 or flexible column redundancy component 113 of FIG. 1A. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 605, one or more errors associated with one or more stored data items corresponding to a first address range of the one or more address ranges is detected. For example, a processing device (e.g., flexible column redundancy component 113) can detect one or more errors associated with one or more stored data items corresponding to a first address range of the one or more address range. In at least one embodiment, the one or more errors can be single bit, double bit, or other errors associated with bit lines or page buffers as described with reference to FIG. 1. For example, the processing device can detect a defective byte as described with reference to FIG. 4—e.g., determine a defective byte 430 in address range 415-a. In some embodiments, the processing device can receive a memory address associated with a first address range of the one or more address ranges. In such embodiments, the processing device can detect one or more errors associated with the memory address.

At operation 610, the processing device determines whether a number of one or more data items address range exceeds a number of available redundant memory locations for the first address range. For example, a processing device can determine that a number of data items of the one or more stored data items exceeds a number of available redundant memory locations for the first address range. As described with reference to FIGS. 2-4, a respective address range of memory device 130 can use a threshold number of redundant locations—e.g., each address range can use a number of redundant memory locations configured to replace defective stored data items. In one embodiment, the processing device can determine the number of data items exceed the number of available redundant memory locations utilizing the content addressable memory (CAM) as described with reference to FIG. 2. For example, the processing device can receive a memory address associated with the first address range and compare the received memory address with a second stored memory address associated with the received memory address—e.g., the CAM can look up the received memory address in a table storing all memory addresses, and determine a physical location(s) associated with the received memory address. In such examples, the processing device can determine redundant memory locations for the first address range are utilized—e.g., the CAM can determine the physical locations including the number of redundant bytes utilized for the received memory address. In other embodiments, the processing device can determine the number of data items exceed the number of available redundant memory locations based on inputs received at a multiplexer (e.g., multiplexer 255 as described with reference to FIG. 2)—e.g., the multiplexer 255 can allow the memory device 130 to determine a number of redundant memory locations used for the received memory address and whether the number of redundant memory locations satisfies the threshold number of redundant memory locations available. For example, the processing logic can compare the received memory address with a second stored memory address indicating a physical location associated with the memory address and determine a number of unavailable redundant memory locations responsive to comparing the received memory address. In such embodiments, the processing logic can determine a difference between a threshold number of available redundant memory locations and the number of unavailable redundant memory locations—e.g., determine the number of available redundant memory locations. In at least one embodiment, the processing logic can compare the difference with the number of one or more stored data items, where the processing logic can determine the number of one or more stored data items exceeds the number of available redundant memory locations responsive to the comparison.

Responsive to determining, at operation 610, that the one or more stored data items exceed a number of available redundant memory locations for the first address range, the processing device, at operation 615, remaps an association of a first memory address from a first address within the first address space to a second address in a second address range of the one or more address ranges, where the second address range comprises one or more available redundant memory locations. For example, a processing device can remap an association of a first memory address of at least one of the stored data items from a first address associated with the first address space to a second address in a second address range of the plurality of address ranges, wherein the second address range comprises one or more available redundant memory locations. In one embodiment, the processing device can remap from the first address (e.g., a defective byte 430 of address range 415-a) to a second address (e.g., to a location previously occupied by an error free byte 420 of address range 415-e) as described with reference to FIG. 4. In such embodiments, the processing device can utilize an available redundant memory location for the second address range (e.g., of address range 415-e) to repair at least one error—e.g., utilize available redundant location 440 of address range 415-e to replace the defective byte 430). Accordingly, the second physical address is associated with a redundant memory cell for the second address range. In some embodiments, the processing logic can determine a number of the one or more available redundant memory locations in the second address range satisfies the number of physical locations of the one or more physical locations before remapping the first address to the second address—e.g., determine a number of the one or more available redundant memory locations for the second address range satisfies the number of errors of the one or more errors. For example, the processing logic can track a number of used redundant locations for each respective address range and determine an address range that has enough redundant locations available to satisfy the number of errors. In one embodiment, the processing device is configured to remap from the first address of the one or more stored data items to the second address before the address is received at a predecoder of the memory device. In another embodiment, the processing logic is configured to remap from the first address of the one or more stored data items to the second address at a predecoder of the memory device. In at least one embodiment, the processing device can remap from the first address to the second address based on a memory management algorithm—e.g., the processing device can determine to repair the defective byte based on the memory management algorithm as described with reference to FIG. 2. In one embodiment, the processing device can receive the memory address associated with the first address range and determine at least one physical location associated with the memory address is at a redundant memory data item of the second address range—e.g., the processing device can utilize a decoder (e.g., decoder 330) to determine an address remap of at least one physical location from the first address range to the redundant memory data item.

In at least one embodiment, the processing logic can detect one or more errors associated with one or more stored data items corresponding to the second address range of the one or more address ranges after remapping the first memory address. The processing logic can determine that a number of the one or more stored data items exceeds a number of available redundant more locations responsive to remapping the association of the first memory address. In at least one embodiment, the processing logic can remap an association of a second memory address of at least one of the stored data items from a third address within the second address space to a fourth address in a third address range of the one or more address ranges, wherein the third address range comprises one or more available redundant memory locations.

In one embodiment, the processing logic can detect one or more additional errors associated with the one or more stored data items corresponding to the first address range. In some embodiments, the processing logic can determine the number of the one or more stored data items exceeds the number of available redundant memory locations for the first address range. The processing logic can also determine the number of the one or more stored data items exceeds the number of available redundant memory locations for the second address range. In some embodiments, the processing logic can remap an association of a second memory address of at least one of the stored data items from a third address within the first address space to a fourth address in a third address range of the one or more address ranges, wherein the third address range comprises one or more available redundant memory locations.

In some embodiments, the processing logic can receive the memory address and determine at least one physical address associated with the memory address is at a redundant memory location within the second address range.

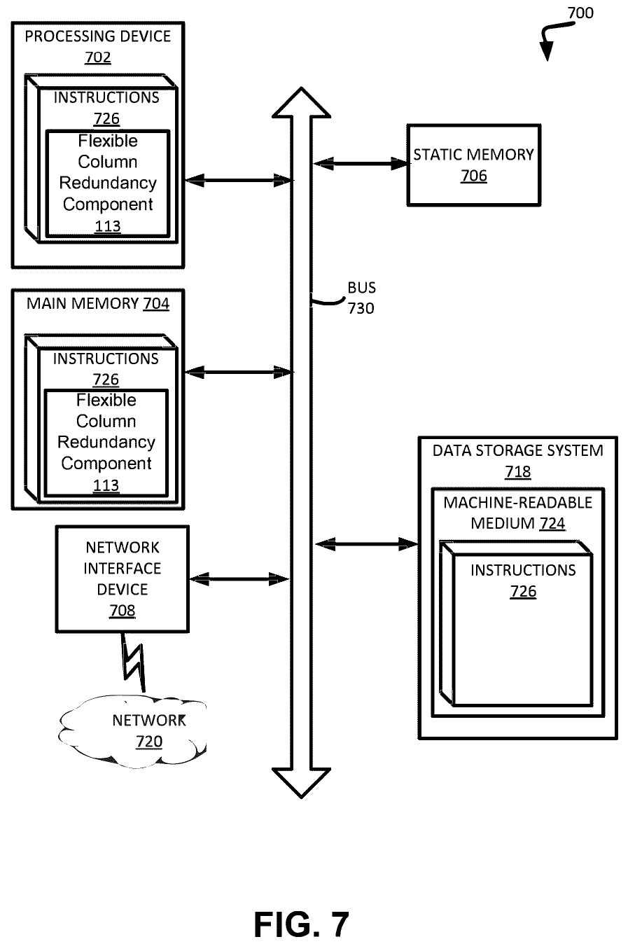

FIG. 7 illustrates an example machine of a computer system 700 within which a set of instructions, for causing the machine to perform any one or more of the methodologies discussed herein, can be executed. In some embodiments, the computer system 700 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to flexible column redundancy component 113 of FIG. 1 to perform operations). In one embodiment, the flexible column redundancy component 113 is configured to repair one or more errors of main memory 704 by utilizing redundant or spare bytes. In one embodiment, the main memory 704 can be divided into address ranges, where each address range has a number of available redundant bytes. The flexible column redundancy component 113 is configured to utilize all of the available redundant bytes to fix one or more errors associated with the respective address range. In some embodiments, the flexible column redundancy component 113 can determine a number of available redundant bytes in a respective address range fails to satisfy (e.g., be equal to or more than) a number of errors in the respective address range. In such embodiments, the flexible column redundancy component 113 can swap a physical address associated with a first address range with unavailable redundant bytes to a physical address associated with a second address range, where the second address range has available redundant bytes. The flexible column redundancy component 113 can utilize the available redundant bytes of the second address range to fix the one or more errors after swapping the physical address from the first address range to the second address range. In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 700 includes a processing device 702, a main memory 704 (e.g., read-only memory (ROM), flash memory, dynamic random access memory (DRAM) such as synchronous DRAM (SDRAM) or RDRAM, etc.), a static memory 706 (e.g., flash memory, static random access memory (SRAM), etc.), and a data storage system 718, which communicate with each other via a bus 730.

Processing device 702 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 702 can also be one or more special-purpose processing devices such as an application specific integrated circuit (ASIC), a field programmable gate array (FPGA), a digital signal processor (DSP), network processor, or the like. The processing device 702 is configured to execute instructions 726 for performing the operations and steps discussed herein. The computer system 700 can further include a network interface device 708 to communicate over the network 720.

The data storage system 718 can include a machine-readable storage medium 724 (also known as a computer-readable medium) on which is stored one or more sets of instructions 726 or software embodying any one or more of the methodologies or functions described herein. The instructions 726 can also reside, completely or at least partially, within the main memory 704 and/or within the processing device 702 during execution thereof by the computer system 700, the main memory 704 and the processing device 702 also constituting machine-readable storage media. The machine-readable storage medium 724, data storage system 718, and/or main memory 404 can correspond to the memory sub-system 110 of FIG. 1.

In one embodiment, the instructions 726 include instructions to implement functionality corresponding to flexible column redundancy component 113 to perform memory access operations initiated by the processing device 702. While the machine-readable storage medium 724 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A memory device comprising:
a memory array comprising a plurality of memory cells addressable by respective addresses that are grouped into one or more address ranges; and
control logic, operatively coupled with the memory array, to perform operations comprising:
detect one or more errors associated with one or more stored data items corresponding to a first address range of the one or more address ranges;
determine that a number of the one or more stored data items exceeds a number of available redundant memory locations for the first address range; and
remap an association of a first memory address of at least one of the stored data items from a first address within the first address range to a second address in a second address range of the one or more address ranges, wherein the second address range comprises one or more available redundant memory locations.

2. The memory device of claim 1, wherein the control logic is to perform further operations comprising:
detect one or more errors associated with one or more stored data items corresponding to the second address range of the one or more address ranges;
determine that a number of the one or more stored data items exceeds a number of available redundant memory locations responsive to remapping the association of the first memory address; and
remap an association of a second memory address of at least one of the stored data items from a third address within the second address range to a fourth address in a third address range of the one or more address ranges, wherein the third address range comprises one or more available redundant memory locations.

3. The memory device of claim 1, wherein the control logic is to perform further operations comprising:
detect one or more additional errors associated with the one or more stored data items corresponding to the first address range;
determine the number of the one or more stored data items exceeds the number of available redundant memory locations for the first address range;
determine the number of the one or more stored data items exceeds the number of available redundant memory locations for the second address range; and
remap an association of a second memory address of at least one of the stored data items from a third address within the first address range to a fourth address in a third address range of the one or more address ranges, wherein the third address range comprises one or more available redundant memory locations.

4. The memory device of claim 1, wherein to determine the number of one or more data items exceed the number of available redundant memory locations, the control logic is to perform operations comprising:
receive a memory address associated with the first address range;
compare the received memory address with a second stored memory address indicating a physical location associated with the memory address; and
determine a number of unavailable redundant memory locations.

5. The memory device of claim 4, wherein the control logic is to further perform operations comprising:
determine a difference between a threshold number of available redundant memory locations and the number of unavailable redundant memory locations;
compare the difference with the number of one or more stored data items, wherein the control logic can determine the number of one or more stored data items exceeds the number of available redundant memory locations responsive to the comparison.

6. The memory device of claim 1, wherein to remap the association of the first memory address from the first address of the one or more stored data items to the second address in the second address range, the control logic is to perform operations comprising:
determine a number of the one or more available redundant memory locations in the second address range is equal to or exceeds the number of errors of the one or more errors.

7. The memory device of claim 1, wherein the control logic is configured to remap the association of the first memory address before a predecoder of the memory device receives the first address.

8. The memory device of claim 1, wherein the control logic is configured to remap the association of the first memory address at a predecoder of the memory device.

9. A method comprising:
detecting one or more errors associated with one or more stored data items corresponding to a first address range of one or more address ranges, wherein memory cells are addressable by respective addresses of the one or more address ranges;
determining that a number of the one or more stored data items exceeds a number of available redundant memory locations for the first address range; and
remapping an association of a first memory address of at least one of the stored data items from a first address within the first address range to a second address in a second address range of the one or more address ranges, wherein the second address range comprises one or more available redundant memory locations.

10. The method of claim 9, further comprising:
detecting one or more errors associated with one or more stored data items corresponding to the second address range of the one or more address ranges;
determining that a number of the one or more stored data items exceeds a number of available redundant memory locations responsive to remapping the association of the first memory address; and
remapping an association of a second memory address of at least one of the stored data items from a third address within the second address range to a fourth address in a third address range of the one or more address ranges, wherein the third address range comprises one or more available redundant memory locations.

11. The method of claim 9, further comprising:
detecting one or more additional errors associated with the one or more stored data items corresponding to the first address range;
determining the number of the one or more stored data items exceeds the number of available redundant memory locations for the first address range;
determining the number of the one or more stored data items exceeds the number of available redundant memory locations for the second address range; and
remapping an association of a second memory address of at least one of the stored data items from a third address within the first address range to a fourth address in a third address range of the one or more address ranges, wherein the third address range comprises one or more available redundant memory locations.

12. The method of claim 9, further comprising:
receiving a memory address associated with the first address range;
comparing the received memory address with a second stored memory address indicating a physical location associated with the memory address; and
determining a number of unavailable redundant memory locations for the first address range.

13. The method of claim 12, further comprising:
determining a difference between a threshold number of available redundant memory locations and the number of unavailable redundant memory locations; and
comparing the difference with the number of one or more stored data items, wherein determining the number of one or more stored data items exceeds the number of available redundant memory locations is responsive to the comparison.

14. The method of claim 9, further comprising:
determining a number of the one or more available redundant memory locations in the second address range satisfies the number of errors of the one or more errors, wherein remapping the association of the first memory address from the first address of the one or more stored data items to the second address in the second address range is responsive to determining the number of the one or more available redundant memory locations.

15. The method of claim 9, wherein remapping the first memory address from the first address to the second address is before a predecoder of a memory device receives the first memory address.

16. The method of claim 9, wherein remapping the first memory address from the first address to the second address is at a predecoder of a memory device.

17. A memory device comprising:
a memory array comprising a plurality of memory cells addressable by respective addresses that are grouped into one or more address ranges;
control logic, operatively coupled with the memory array, to perform operations comprising:
receiving a memory address;
detect one or more errors associated with the memory address corresponding to a first address range of the one or more address ranges;
determine a number of one or more errors fails to satisfy a number of redundant memory locations for the first address range; and
remap an association of the memory address from a first address within the first address range to a second address associated with a second address range, wherein the second address range comprises one or more available redundant memory locations.

18. The memory device of claim 17, wherein the control logic is to further:
determine a number of the one or more available redundant memory locations is equal to or exceeds the number of errors of the one or more errors.

19. The memory device of claim 17, wherein the control logic is to perform operations comprising:
receive the memory address; and
determine at least one physical address associated with the memory address is at a redundant memory location within the second address range.

20. The memory device of claim 17, wherein the control logic is configured to remap the association of the first address before a predecoder of the memory device receives the first address.
